(19) United States
(12) Patent Application Publication
(10) Pub. No.: US 2002/0030546 A1
(43) Pub. Date: Mar. 14, 2002

(54) Frequency synthesizer having an offset frequency summation path

(76) Inventor: Pierce Vincent Keating, Issaquah, WA (US)

Correspondence Address: PIERCE V. KEATING, 3573 253RD CT. SE, ISSAQUAH, WA, 98029, US

(21) Appl. No.: 09/897,527

(22) Filed: Jun. 29, 2001

Related U.S. Application Data
(63) Continuation-in-part of application No. 09/584,679, filed on May 31, 2000.

(51) Int. Cl. H03L 7/07; H03L 7/18; H03L 7/197

(52) U.S. Cl. 331/2; 331/25

(57) ABSTRACT

A frequency synthesizer having finer frequency resolution with lower spurious fractional noise energy employs an offset frequency summation path. An offset frequency is generated using the output of a fractional frequency divider. In the frequency domain, the offset frequency is added to the output frequency of a variable frequency oscillator to produce an output frequency.

### FIELD OF THE INVENTION

The present invention relates to frequency synthesizers and more particularly to frequency synthesizers having offset frequency summation paths.

### DESCRIPTION OF THE PRIOR ART

Frequency synthesizers having a phase-locked loop (PLL) topology are well known in the art and are commonly employed to generate one of several possible signal frequencies, which are used in many types of electronic systems such as communications equipment. A conventional PLL-type frequency synthesizer, or conventional synthesizer loop, typically receives a reference frequency signal, which is selected to have a very stable frequency with minimum sideband or phase noise. The conventional synthesizer loop generally includes a phase detector which has one input coupled to a reference frequency signal, and a phase error output signal, which is coupled to control a voltage controlled oscillator (VCO). The signal produced by the VCO is usually considered the output of the frequency synthesizer and this signal is also applied to a frequency divider circuit, or loop divider, which in turn generates a signal having a frequency which is lower than that of the signal output from the VCO by a factor of the modulus value of the loop divider. The signal output by the loop divider is coupled to a second input of the phase detector to form a negative feedback loop. The phase detector circuit operates such that a particular error signal is output when the phase of reference frequency signal is different than that of the divided frequency signal. The polarity of the error signal is chosen to direct the frequency of the VCO output signal such that the phase difference between the divided frequency signal and the reference frequency signal is minimized. As the value of the loop divider is incremented or decremented by integer values, the VCO output signal will be incremented or decremented in frequency by corresponding multiples of the reference frequency. Unwanted spurious energy is also usually present in the frequency synthesizer output at the fundamental and harmonic frequencies of the reference signal. The unwanted energy is typically attenuated by low pass filtering the phase detector output. In order to achieve a small frequency step at the output of the synthesizer using a integer valued loop divider, a relatively low valued reference frequency must be used which in turn results in a relatively high valued loop divider and a relatively narrowband loop filtering requirement. A high valued loop divider is undesirable since noise energy, which is generated by elements in the loop, will be present at the frequency synthesizer output and will be multiplied in power by the value of the loop divider. Further, a loop filter having a narrow bandwidth is undesirable because the loop settling time is increased and the rejection of VCO sideband noise is decreased.

In order to alleviate some of the problems associated with a frequency synthesizer having a relatively small frequency step size, it is known to use a programmable fractional loop divider in which the loop divider value is periodically changed in order to obtain an average divide value. A fractional loop divider enables both a high valued reference frequency and a relatively low valued loop divider to be used, as compared with an integer modulus loop divider, since the synthesizer output frequency will be equal to fractional multiples of the reference frequency. However the fractional divider will also introduce spurious energy at subharmonics of the reference frequency. As a mathematical approximation, the fractional divider may be modeled as a constant fractional number, and the periodic change in the divide value may be modeled as an additive phase disturbance signal at the input of the loop divider. The subharmonic spur energy will affect the output of a conventional single-loop frequency synthesizer as follows:

f₀=(fᵣ+fₛ/(N+Nu/D))*(N+Nu/D)+fᵣ*(N+Nu/D)fₛ

where f₀ represents the VCO out frequency, fᵣ represents the reference frequency, N represents the integer modulus of the loop divider, Nu represents a numerator value, D represents a denominator value and fₛ represents the subharmonic fractional spur energy. Notice that for this general synthesizer loop architecture, the subharmonic spurs will not be attenuated at the synthesizer output except for the low pass filtering of the synthesizer loop.

A fractional loop divider usually includes a programmable divider and a divider control portion. The divider control portion periodically controls the modulus of the programmable divider, and often includes one or more accumulator circuits. An accumulator is programmed to have a particular capacity or denominator, and is incremented by a programmed numerator value for each output cycle of the programmable divider. When the contents of the accumulator equal or exceed the value of the denominator, a carry output is generated and any remainder is left in the accumulator. Typically a carry output will momentarily increment or decrement the programmable divider modulus by one. The periodic change in the divider modulus will introduce spurious noise energy at frequencies which are lower than the output of the divider. If the PLL frequency synthesizer is locked it may be assumed that the output frequency of the programmable divider will equal the reference frequency.

Compensation techniques using multiple accumulators have been developed such that the subharmonic reference spurs, which are produced by the fractional loop divider, are reduced in amplitude thereby enabling a wider loop filter bandwidth. Multiple accumulator fractional dividers typically include a programmable divider and a first accumulator programmed with a numerator and a denominator, and a second accumulator having the same denominator as the first accumulator. The second accumulator integrates the contents of the first accumulator by adding the contents of the first accumulator to the second accumulator contents for each clock cycle of the programmable divider output. Both accumulators are clocked by the output of the associated loop divider or by the reference frequency. The programmable divider modulus is controlled by sum of the carry output of the first accumulator and the derivative of the second accumulator carry output. Fractional N frequency dividers are also known such that fractional spur attenuation is accomplished through the use of sigma-delta architectures. Like sigma-delta analog-to-digital converters, compensated fractional N frequency synthesizers are intended to move much of the quantization noise to high frequencies where it is more easily filtered. In fact, it has been shown in U.S. Pat. No. 5,166,642 that z-domain transfer functions for sigma-delta converters and compensated fractional N frequency synthesizers are quite similar. In general, a high degree of subharmonic spur compensation can be achieved by increasing the number of accumulators used in the divider control circuit and increasing reference frequency. It has been shown that very fine frequency tuning, on the order of 10 Hz or less, can be achieved with relatively low amplitude subharmonic fractional spurs, with a fractional N frequency divider having multiple accumulators.

Other methods for minimizing the effects of spurs caused by fractional N frequency division in frequency synthsizers are known, such as multiple parallel accumulators used to periodically modify the modulus of a loop divider, and through a variable loop divider based on successive rows in a Pascal's traingle. Further discussion of fractional compensation techniques for frequency synthesizers can be found in U.S. Pat. Nos. 4,816,774, 5,055,802, 5,038,117, 4,609,881, 4,204,174, 5,777,521, 5,079,521 and 4,965,531.

When a high order of spur compensation is used in a fractional loop divider, such as through the use of three or more accumulators, the subharmonic spurs will be further decreased in amplitude, but the loop divider itself will still require a relatively large minimum divide value. For example, a compensated fractional divider having two accumulators will require an integer divider having at least 4 adjacent divide values, while a compensated fractional divider having four accumulators will require an integer divider having at least 16 adjacent divide values. Therefore while compensated fractional loop dividers help to reduce the amplitude of subharmonic spurs, and thereby enable a wide bandwidth frequency synthesizer, as the order of the compensation is increased the minimum value of the loop divider will also increased. Noise which is generated by elements of the synthesizer loop, including the subharmonic spur energy produced by the fractionalized divider, will be multiplied by the value of the loop divider thereby increasing the noise in the output spectrum of the synthesizer and tending to require a loop filter with a relatively narrow bandwidth. It would therefore be beneficial to construct a frequency synthesizer which has a loop divider value which is independent of the method and means of obtaining relatively fine frequency tuning, such as a fractional divider, and thus may be arbitrarily set to a value which will minimize or eliminate the divider's multiplicative effect on noise. It would also be beneficial to construct a fractional N frequency synthesizer which will further attenuate inband fractional subharmonic spurs, in addition to the attenuation obtained through fractional spur compensation techniques.

The minimum frequency resolution which is typically obtained by a single loop conventional PLL type fractional N frequency synthesizer, is the reference frequency divided by the fractional denominator of the loop divider. Thus for very fine frequency resolution in conjunction with a large valued reference frequency, a relatively large accumulator circuit must be used since the denominator or capacity of the accumulator must be large. An efficiency improvement would be realized if similar frequency resolution could be obtained with a lower degree of fractionalization and consequently, a smaller denominator value.

### BRIEF DESCRIPTION OF THE DRAWINGS

FIG. 1 illustrates a first embodiment of a frequency synthesizer in accordance with the present invention.

FIG. 2 includes a second embodiment of a frequency synthesizer in accordance with present invention

FIG. 3 depicts the operation of an XOR gate used as a frequency summation device.

FIG. 4 illustrates a fourth embodiment of a frequency synthesizer in accordance with the present invention.

FIG. 5 illustrates a fifth embodiment of a frequency synthesizer in accordance with the present invention.

FIG. 6 illustrates a sixth embodiment of a frequency synthesizer in accordance with the present invention.

FIG. 7 illustrates a seventh embodiment of a frequency synthesizer in accordance with the present invention.

FIG. 8 illustrates a seventh embodiment of a frequency synthesizer in accordance with the present invention.

### DESCRIPTION OF THE PREFERRED EMBODIMENT

The present invention is comprises a frequency synthesizer based on a modified synthesizer loop structure. In this discussion, a conventional synthesizer loop is synonymous with a conventional PLL-type frequency synthesizer and includes a reference frequency, phase detector, VCO, and loop divider in the well-known and conventional arrangement. In general, a conventional synthesizer loop can be a phase-locked loop, frequency-locked loop or a delay-locked loop. The modified synthesizer loop, as used in the present invention, is a negative feedback loop, which includes a reference frequency, phase detector and VCO, as well as a feedback path, which includes a frequency summation path. As will be shown, the use of a frequency summation path in the modified synthesizer loop provides for a transfer function, which is significantly different, when compared to a conventional synthesizer loop and exhibits significantly improved performance over that of a conventional synthesizer loop.

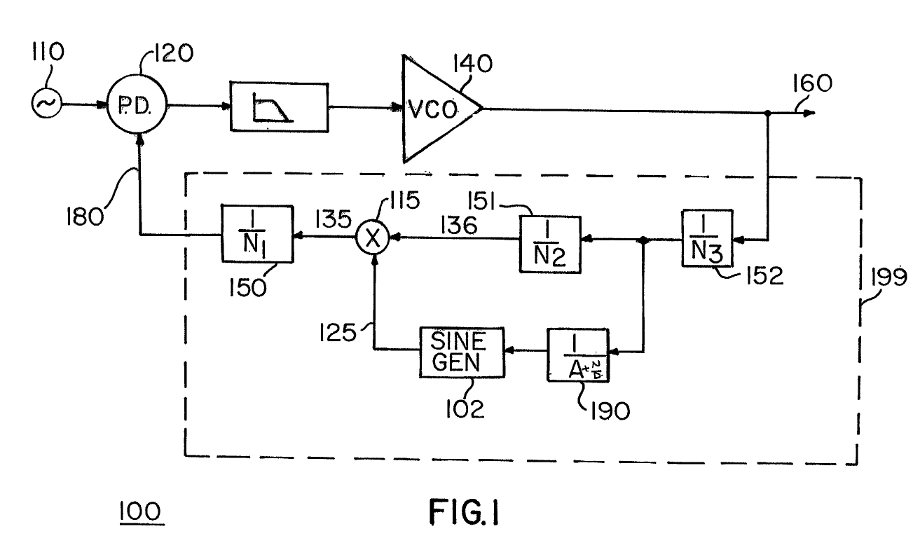

Referring to FIG. 1, a frequency synthesizer comprises a modified synthesizer loop including a feedback path (199). The feedback path (199) comprises a secondary loop divider (151), having a divide modulus N₂, which produces a secondary divided signal (136). The feedback path (199) further comprises a frequency summation device (115), and an offset divider (190). The frequency summation device (115) has a first input coupled to receive the secondary divided signal (136), and a second input coupled to receive an offset signal (125) output by the offset divider (190). The secondary loop divider (151) and the offset divider (190) are coupled to the synthesizer output signal (160) through a coupling divider (152) having a divide modulus N₃. In operation, the secondary divided signal (136) is added, in the frequency domain, with an offset signal (125) through a frequency summation device (115) to produce an intermediate signal (135). For the purposes of this discussion, the term “frequency summation” is used to describe the combination of two input signals, which produces an output signal having a frequency described by:

f₀=D*f_{c}+fₘ

or

f₀=D*f_{c}−fₘ

where f₀ is the frequency output by the frequency summation device, f_{c} is a relatively high frequency input to the frequency summation device, fₘ is a relatively low frequency input to the frequency summation device and D is a factor by which the high frequency input f_{c} is modified in frequency.

Preferably, in FIG. 1, the frequency summation device (115) is an image-balanced mixer configured to generate either the sum or the difference of the secondary divided signal (136) frequency and the offset signal (125) frequency. When an image-balanced mixer is used as a frequency summation device (115), it is necessary that the offset signal (125) and the secondary divided signal (136) be input to the frequency summation device (115) as complex signal types, in order to suppress the unwanted upper or lower sideband. Means for obtaining a 90 degree phase shifted version of both the secondary divided signal (135) and the offset signal (125), is assumed to be incorporated within the frequency summation device (115), the offset divider (190), the sine generator (102), the secondary loop divider (151), the coupling divider (152) or the variably controlled oscillator (VCO)(140). A loop divider (150) is also included in the feedback path (199) and is coupled to receive the intermediate frequency (135), and output a feedback signal (180). When the loop divider (150) has a divide value of greater than 1, it is typically employed for coarse tuning of the frequency synthesizer or merely for multiplication of the reference frequency to a higher frequency. When the secondary loop divider (151) has a divide value of greater than 1, it is typically employed to increase the frequency tuning range output from the offset divider (190) and for multiplication of the reference frequency to a higher frequency, as well as coarse tuning of the frequency synthesizer. When the coupling divider (152) has a divide value of greater than 1, it is typically used for multiplication of the reference frequency at the synthesizer output or to provide a complex signal for the frequency summation device (115). The steady state frequency of the synthesizer output signal (160) is described as a function of the reference frequency (110) by

f₀=fᵣ*N₁*N₂*N₃*A/(N₂+A)

and

f₀=fᵣ*N₁*N₂*N₃*A/(N₂−A)

where the frequency summation device (115) is configured to produce the sum and difference respectively of the secondary divided signal (160) frequency and the offset signal (125) frequency, and where f₀ represents the frequency of the synthesizer output signal (160), fᵣ represents the reference frequency (110), N₁ represents the divide value of the synthesizer loop divider (150), N₂ represents the divide value of the secondary loop divider (151), and A represents the divide value of the offset divider (190).

Preferably, the offset divider (190) is a fractional frequency divider. In general, a fractional frequency divider periodically changes it's divide value between two or more values over time, to provide a particular average divide value. Because the frequency at which the divide values are changed is lower than the fundamental frequency output from a fractional frequency divider, additional spurious energy is generated which is at frequencies lower than the output frequency of the fractional frequency divider. The spurious energy is a result of the periodic phase changes or disturbances of a fractionally divided waveform. When a signal having subharmonic fractional spurs is divided in frequency, the phase disturbances are decreased in amplitude as the period of the divided signal is increased. For example, the output of a fractional divider which is based on a divider modulus of 20 and 21, will have fractional spurs which are approximately 10 times smaller then those of a fractional divider output based on a divider modulus of 2 and 3. Preferably the offset divider (190) is a fractional frequency divider having multiple accumulators, and is capable of very fine frequency resolution with relatively low amplitude fractional subharmonic spurs.

Taking into account the fractional noise energy generated by the offset divider, the frequency of the synthesizer output signal (160) is described by

f₀=(fᵣ*N₃N₂*N₁*A)/(A+N₂)+(N₃*N₂*fₛ)/(A+N₂)

and

f₀=(fᵣ*N₃*N₂*N₁*A)/(A−N₂)+(N₃*N₂*fₛ)/(A−N₂)

for the sum and difference frequencies respectively of the frequency summation device (115), where fₛ represents the amplitude of fractional spurs generated by the offset divider (190).

Notice that when the secondary loop divider (151) N₂ and the coupling divider (152) N₃ are equal to one, the fractional noise is reduced in amplitude at the synthesizer output signal (160) by approximately a factor of the offset divider (190) modulus represented by A. Thus, the fractional noise contributed by the offset divider (190) is not amplified by the loop gain of the frequency synthesizer, as with a typical fractional N loop divider, but is instead attenuated by the divide value of the offset divider (190) before being added to the synthesizer output signal (160). If an efficient fractional divider is constructed using known dual modulus pulse swallowing techniques, this represents a typical reduction in subharmonic fractional spur noise in the output of the present invention of 30 to 40 dB for a four accumulator fractional divider over most practical single loop fractional N frequency synthesizer topologies. Also, the loop divider (150) may be set to an arbitrarily low integer or fractional value, if desired, to minimize the effect of loop gain on noise generators within the loop. Further, the value of the loop divider (150) N₁ may be set to any nonzero integer or fractional value, independent of the structure of the offset divider (190).

As the value of the secondary loop divider (151) N₂ is increased from 1, the range of frequency tuning provided by the offset divider (190) will be increased. In some configurations of the frequency synthesizer (100), such as when the loop divider (150) equal to 1, it may be useful to increase the frequency tuning range of the offset divider (190) through the inclusion of a secondary loop divider (151)(N₂>1). Also, when it is desired to provided a relatively low valued reference frequency, the secondary loop divider (151) may be used to multiply the reference frequency at the frequency synthesizer output, similar in operation to the loop divider (150). However, when a secondary loop divider (151) is included in the frequency synthesizer shown in FIG. 1, the fractional subharmonic spurs generated by the offset divider (190) will be increased in amplitude. For these reasons in part, the use of a secondary loop divider (151), and the divide value chosen, becomes a design tradeoff and parameter in the design of the frequency synthesizer (100).

When a coupling divider (152) is used (N₃>1), it is typically for multiplication of the reference frequency at the synthesizer output, or to provide a quadrature signal to the frequency summation device (115). However, the use of a coupling divider (152) will increase the amplitude of fractional spurs by a factor of the divide value of the coupling divider (152) N₃ at the output of the frequency synthesizer (100).

The type of frequency summation device (115) used in the frequency synthesizer (100), and the performance characteristics of a particular frequency summation device (115), are important parameters in the frequency synthesizer (100) design. For example, in order to attenuate or substantially eliminate undesired spurious products at the synthesizer output (160), it is preferred to use an image-balanced mixer as a frequency summation device (115). Other digital frequency summation devices may be used in place of an image-balanced mixer, such as an XOR gate. However the digital signal produced by an XOR gate in the present invention, will comprise a relatively high frequency synthesizer output signal (160) summed in the frequency domain, with a relatively low frequency offset signal (125). Large harmonics of the low frequency offset signal (125) will be present in the output signal spectrum of the frequency summation device (115), when digital frequency summation device, such as an XOR gate is used for frequency summation. When a loop divider (150) having a divide modulus greater than one is coupled to the output of the frequency summation device (115), it is preferable to provide an intermediate signal (135) which has a frequency spectrum with relatively low amplitude harmonic spurs related to the offset signal (125). Because a frequency divider operates by downsampling an input signal, the signal input to the loop divider (150) must be bandlimited to avoid aliasing at the output of the loop divider (150). Consequently, if the intermediate signal (135) has non-harmonically related spurious products, the spectrum of the loop divider output signal (180) may have non-harmonically related spurious products which result from aliasing. If the aliased spurs are close to the carrier frequency, the spurs will potentially fall within the frequency synthesizer bandwidth at the phase comparator (120) input, and therefore may appear largely unattenuated in the spectrum of the synthesizer output signal (160).

Preferably, a sine generator (102) is included in the feedback path (199) to substantially eliminate unwanted harmonics from the offset signal (125) at the input of the frequency summation device (115) when a loop divider (150) is used in the frequency synthesizer (100). As shown in FIG. 1, the output of the sine generator (102) is coupled to an input of the frequency summation device embodied as an image-balanced mixer (115). The output of the image-balanced mixer (115) preferably has a relatively linear response to the input of the image-balanced mixer (115), which is coupled to the sine generator (102). If the image-balanced mixer (115) has a very linear response, then the output spectrum of the mixer (115) will contain harmonic sidebands of the offset signal (125), which are substantially no larger than the harmonics present at the output of the sine generator (102). In this discussion, a sine generator block is meant to be representative of several possible embodiments, such as filters, phase-locked loops, and pulse shaping circuits using active and/or passive components, which are intended to attenuate or substantially remove the harmonics of a given input signal. A sine generator (102) might be embodied as a low-pass filter, for example, where the cutoff frequency and order of the filter are designed to attenuate the harmonics of a square wave by a minimum amount, such as −70 dBc from the fundamental frequency.

When the loop divider (150) has a divide value equal to one, it may be possible to use a digital frequency summation device (115), such as an XOR gate, since the intermediate signal (135) is not downsampled before being input to the phase detector (120). Or, if an image balanced mixer is used as a frequency summation device (115), the linear characteristics of the image balanced mixer can be made relatively less stringent, and/or perhaps the sine generator (102) can be substantially eliminated or designed with relatively less harmonic attenuation.

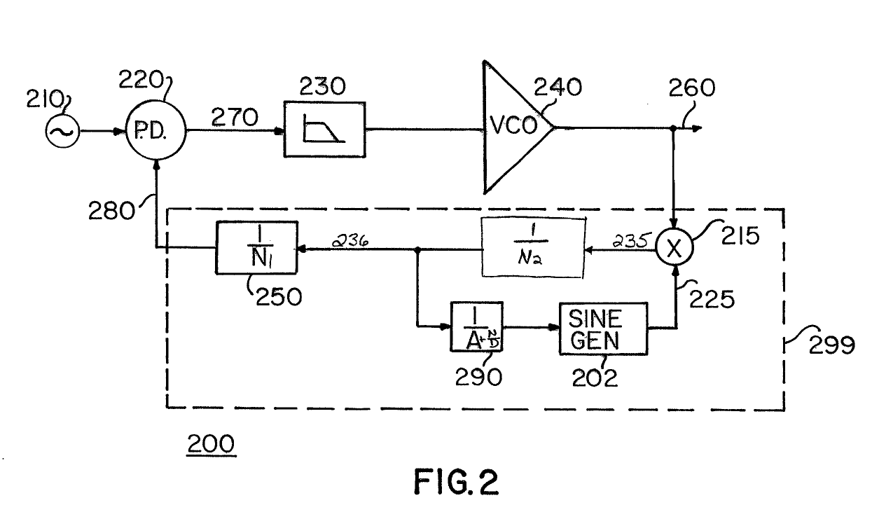

FIG. 2 shows a second embodiment of the present invention, which comprises a modified synthesizer loop having a feedback path (299). The feedback path (299) includes a frequency summation device (215) which has a first input coupled to receive a synthesizer output signal (260). The output of the frequency summation device (215) is coupled to the input of a second loop divider (251). The second input of the frequency summation device (215) is coupled to the output of the second loop divider (251) through an offset divider (290), also included in the feedback path (299). Preferably the offset divider (290) is a fractional frequency divider having one or more accumulators, and is capable of relatively fine frequency resolution.

The frequency summation device (215) may be an image-balanced mixer in order to attenuate unwanted spurious products in the spectrum of the feedback signal (280). Preferably a sine generator (202) is used to couple the offset divider (290) output to the second input of the frequency summation device (215) when the frequency summation device (215) is an image-balanced mixer. When either the first or second loop divider (250 and 251) have a divide value greater than 1, they are generally used for coarse tuning of the frequency synthesizer (200), and to multiply the value of the reference frequency (210) at the synthesizer output (260). Taking into account the fractional spurs generated by the offset divider (290), which are within the bandwidth of the frequency synthesizer (200), the synthesizer output signal (260) is described by

f₀=fᵣ*N₁*(N₂−1/A)+fₛ/A

and

f₀=fᵣ*N₁*(N₂+1/A)+fₛ/A

for the sum and difference frequencies respectively of the frequency summation device (215) where N₁ represents the modulus value of the first loop divider (250), N₂ represents the modulus value of the second loop divider (251), A represents the modulus value of the offset divider (290), fᵣ represents the reference frequency (210) and fₛ represents fractional spurs generated by the offset divider (290).

When the first loop divider (250) has a divide value greater than one and the second loop divider (251) has a divide value of one, the offset divider will run at a frequency relatively close to the synthesizer output (260). Thus, a multiaccumulator offset divider (290) will have a high pass response to fractional spurs with a relatively high corner frequency. However, the bandwidth of relatively high-level spurious products, which are not harmonics of the intermediate signal frequency (2xx), must be kept relatively narrow to avoid aliasing at the output of the first loop divider (250).

For the case where the divide modulus of the second loop divider (251) is an integer greater than one, the frequency of the signal (236) input to the offset divider (290) is reduced. If the offset divider (290) is a multi-accumulator frequency divider, then the high-pass corner frequency response of the divider (290) will tend to be reduced in frequency. This will tend to reduce the level of attenuation of low frequency fractional spurs at the output of the offset divider (290). However, an advantage of this configuration is that the output of second loop divider (251) will not contain discrete aliased spurs from the downsampled output spectrum of the frequency summation device (215). This is because the offset frequency (225) is directly related to the output frequency of the second loop divider (251). Therefore a sine generator (202) is not needed to reduce aliased products in the frequency synthesizer (200) and a digital frequency summation device, such as an XOR gate, may be used without causing aliased products at the output of the loop divider (250).However, the sine generator (202) will reduce integer harmonics related to the fundamental output frequency of the offset divider (290), which may reduce the filtering requirement in the frequency synthesizer thereby improving performance. Further, when the second loop divider (251) has a divide value greater than 1, the offset frequency (225) is lowered, which will tend to lessen the attenuation of low frequency fractional spurs if the offset divider (290) has multiple accumulators.

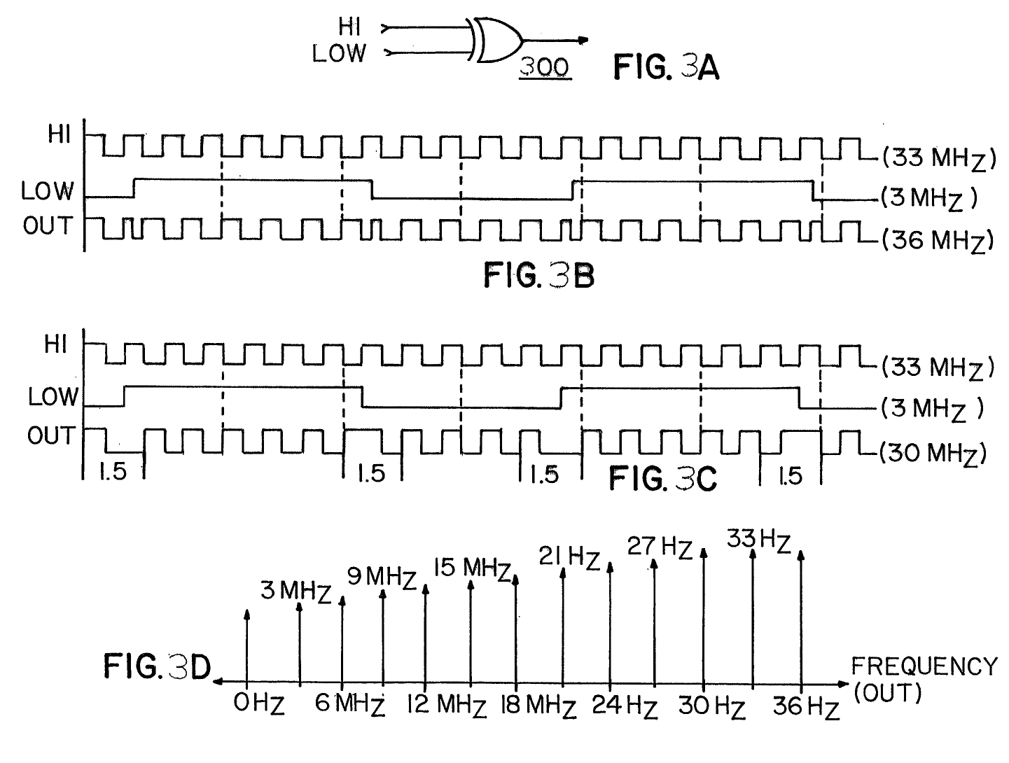

The waveforms shown in FIGS. 3b and 3c illustrate the operation of an OR gate (300) as used for a frequency summation device. In FIG. 3b, a first input signal HI, has a frequency of 33 Mhz, and a second input signal LO has a frequency of 3 Mhz. The positive and negative transitions of the signals HI and LO are skewed in time relative to each other in order to produce an XOR output signal OUT, which is equal to the sum of the two input frequencies. It is observed that the waveform OUT is identical to the input signal HI, except for an additional pulse which is generated for each transition of the LO waveform. This serves to periodically shift the phase of the OUT signal positively by 7 radians for each transition of the input signal LO. The average frequency of the signal OUT is the sum of the HI and LO frequencies, 36 Mhz.

The waveform in FIG. 3c illustrates an XOR frequency summation device used to generate the difference between two input signal frequencies. In FIG. 3c, the positive and negative transitions of the signals HI and LO are aligned relative to each other such that the XOR output signal OUT is equal to the difference of the two input frequencies. The OUT waveform in FIG. 3c contrasts with that of FIG. 3b in that the OUT signal in FIG. 3c is identical to the HI signal except that a pulse is removed for each transition of the LO waveform. The OUT signal is lowered in frequency relative to the HI frequency, by a periodic negative phase shift of π radians for each transition of the input signal LO. Notice that the positive phase transitions of the OUT waveform in FIG. 3c could be reproduced by a pulse swallowing frequency divider having a dual divide modulus of divide by 1 or divide by 1.5. Another analogous structure is a dual modulus divide by 1 or 2, where for each positive transition or for each negative transition of the input signal LO, the divide value is 2, otherwise the divide value is 1. For this case, one full cycle of the HI frequency is swallowed for each positive transition or each negative transition of the input signal LO. In fact, any dual modulus frequency divider having two adjacent divide values can be used as a frequency summation device where the output frequency is equal to the frequency of the HI signal divided by the nominal divide value of the frequency divider, plus or minus the frequency of the LO signal.

FIG. 3d depicts a frequency spectrum, which is representative of the spectrums of the OUT signals in both FIGS. 3b and 3c. Notice that in addition to the desired signal energies at 36 Mhz and 30 Mhz respectively, subharmonic frequencies are also present for both signals, at intervals equal to the frequency of the LO signal. These relatively large, non-harmonically related spurs result from the digital method of frequency summation using an XOR gate.

Thus, the frequency summation device (215) in FIG. 2 can be embodied by an XOR gate, or a dual modulus prescaler having a divide value of 1 or 1.5, or a dual modulus prescaler having two adjacent divide values. When a prescaler is used, the HI frequency from the VCO (260) is coupled to the clock input of the prescaler, and the LO frequency from the offset divider (290) is coupled to the modulus control input.

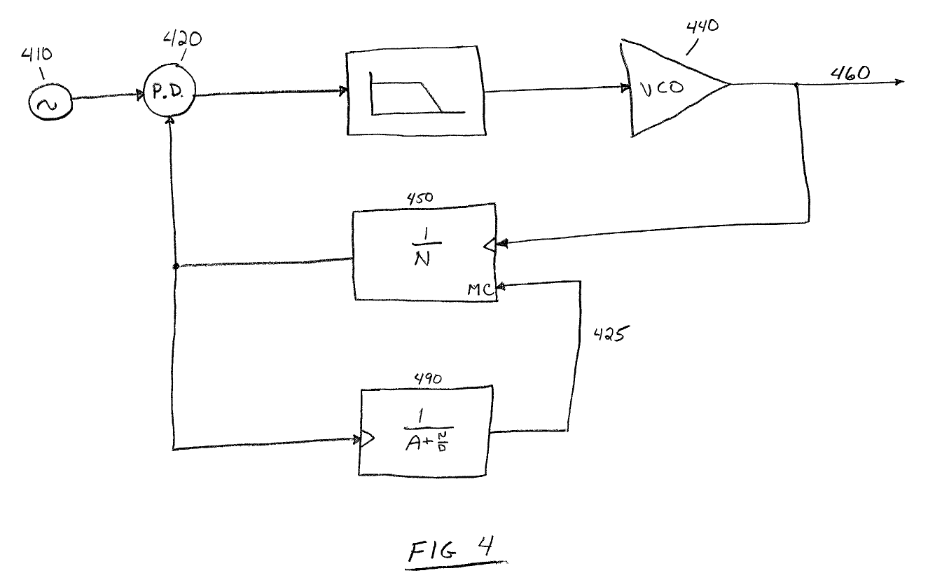

FIG. 4 depicts a frequency synthesizer in which a loop divider (450) having a modulus control input is used as a frequency summation device. The offset divider (490) has a clock input coupled to the output of the loop divider (450) and an output coupled to the modulus control input of the loop divider (450). The frequency synthesizer (400) is differentiated from conventional fractional N frequency synthesizers in that the offset divider (490) is a fractional frequency divider in which the divide modulus is periodically modified in order to produce an average fractional divide value. Further, the modulus control of the loop divider (450) is responsive only to the transitions of the offset signal (425), where the transitions are reflective of the periodic cycles of the offset signal (425). That is, the divide value of the loop divider (450) is equal to a first value when a particular transition polarity of the offset signal (425) is not detected. When the particular transition polarity of the offset signal (425) is detected, the divide value of the loop divider (450) is equal to a second value for at least one output cycle of the loop divider (450). If, when a transition of the offset signal (425) is detected, the loop divider (450) is equal to the second value for only one output cycle of the loop divider (450) and the second value of the loop divider (450) is equal to the first value plus one, the frequency of the offset signal (425) will be subtracted from the nominal frequency of the signal output by the loop divider (450). If, when a transition of the offset signal (425) is detected, the loop divider (450) is equal to the second value for only one output cycle of the loop divider (450) and the second value of the loop divider (450) is equal to the first value minus one, the frequency of the offset signal (425) will be added to the nominal frequency of the signal output by the loop divider (450). In general, the value of the loop divider (450) is modified in accordance with the periodic cycles of the offset signal (425). Further, the periodic modification of the loop divider (450) can occur as a single alteration or as a particular sequence of alterations, which are triggered by the detection of a transition of the offset signal (425). As an example, the feedback path in the frequency synthesizer (400) can be configured such that the loop divider (450) will, upon detection of a positive transition of the offset signal (425), consistently divide by a second value for two or more output cycles of the loop divider (425) instead of just for one output cycle of the loop divider (425). It is important that the particular periodic modification of the loop divider (450), in response to the detection of transitions of the offset signal (425), be applied in a consistent manner so that the spurious energy that results from the modification will be directly related to the frequency of the offset signal (425). If this condition is followed, no unexpected spurious energy will be present at the output of the loop divider (450) due to aliasing.

The offset signal (425) has a period, which periodically varies in order to produce an average and particular frequency desired at the output of the offset divider (490). If, in order to tune to a particular frequency, it is not necessary for the divide value of the offset divider (490) to be periodically modified, the output frequency of the offset divider (490) will remain relatively high. Including the fractional spur energy from the offset divider (490), the synthesizer output signal for frequency synthesizer (400) is described by

f₀=fᵣ*(N−1/(A+Nu/D))+fₛ/(A+Nu/D)

and

f₀=fᵣ*(N+1/(A+Nu/D))+fₛ/(A+Nu/D)

for the sum and difference frequencies respectively of the loop divider (450), used as a frequency summation device, where N represents the divide modulus value of the loop divider (450), A represents the integer modulus value of the offset divider (490), Nu represents the numerator value of the offset divider (490), D represents the denominator value of the offset divider (490), fᵣ represents the reference frequency (410) and fₛ represents fractional spurs generated by the offset divider (490).

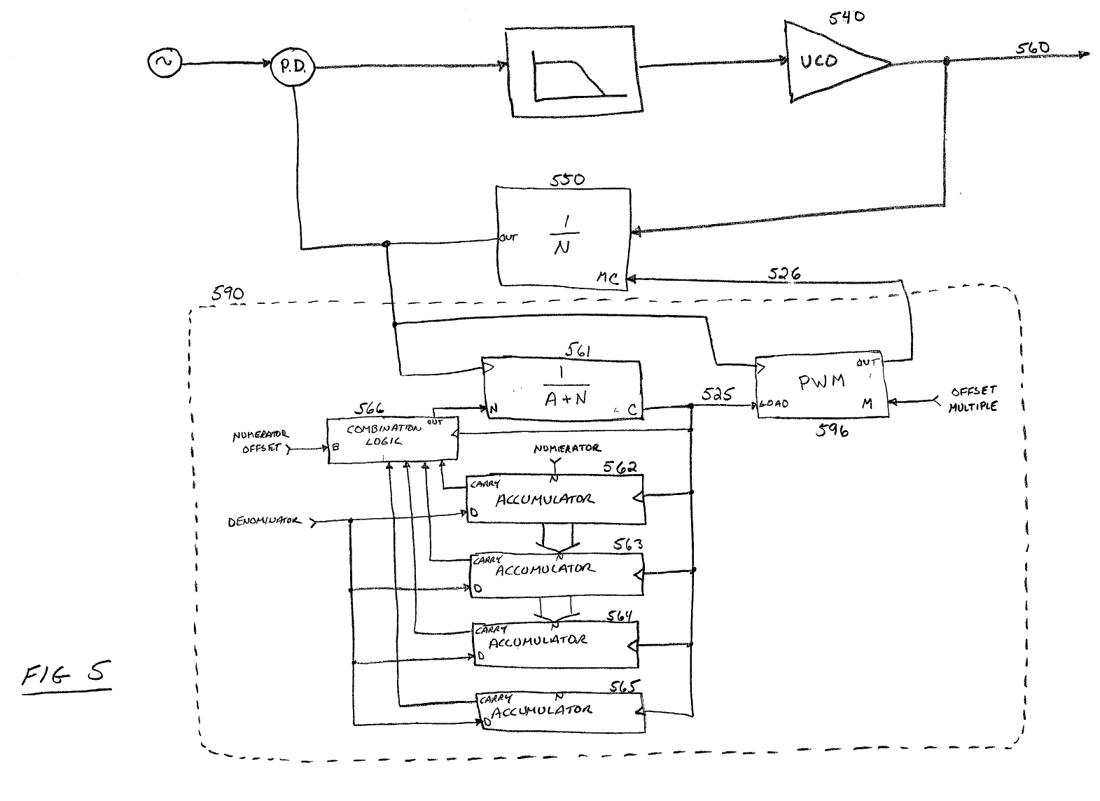

FIG. 5 depicts one of several possible implementations of the frequency synthesizer (400). The loop divider (550) is a pulse swallowing frequency divider. In FIG. 5, frequency summation of a pulse-width-modulated offset frequency (526) and the VCO (540) output frequency is accomplished, in part, through the pulse swallowing action of the loop divider (550). The modulus control input of loop divider (550) is coupled to the output of the offset divider (590) through a pulse width modulator (PWM) circuit (596). The offset divider (590) is a fractional N frequency divider coupled to receive the signal output from the loop divider (550). Equivalently, the offset divider (590) may be coupled to receive the reference frequency (510) since, when locked, the frequency of the signal output by the loop divider (550) is equal to the reference frequency (510).

The offset divider (590) includes a frequency divider (561) having a modulus control input. The frequency divider (561) has a variable divide modulus which is periodically modified by first, second, third and fourth accumulators (562, 563, 564 and 565 respectively). The function of the frequency divider (561) is to provide an offset frequency (525) to be subtracted or added to the VCO output frequency (560). In contrast, a conventional fractional N frequency divider typically uses an accumulator as a means of periodically changing the divide value of a loop divider in order to obtain a fractional divide value and a particular frequency tuning resolution. In general, when used in a conventional fractional N frequency divider, an accumulator does not operate to output a particular frequency, but rather to generate a particular waveform necessary to produce a particular fractional division in the loop divider. This manner of use in a conventional fractional N frequency divider can be demonstrated by observing that, for a given denominator, the frequency output by an accumulator when the numerator is equal to one is the same as when the numerator is equal to the denominator minus one.

In FIG. 5, a first accumulator (562) has a carry output coupled to the modulus control input of frequency divider (561). The first accumulator (562) is programmed with particular numerator and denominator values. It is desirable to maintain a relatively large divide value in the offset divider (590) in order attenuate fractional spurs. However, for multiaccumulator fractional offset divider structures, it is also desirable to keep the frequency output by the offset divider (590) relatively high in order to keep the corner frequency of the high pass response of a multicaccumulator fractional divider high.

In FIG. 5, the loop divider (550) is responsive to a particular logic level at the modulus control input for each output cycle of the loop divider (550). In general, the frequency divider (561) will output a pulse having a width of one period of the output of the loop divider (550) for each cycle of the frequency divider (561) output. However, in order to extend the tuning range of the frequency synthesizer (500), while maintaining a relatively large divide value of the offset divider (590), a PWM circuit (596) is provided to selectively extend the pulse width of the pulses output by the frequency divider (561). The pulse width of the frequency divider (561) output pulse is selectively increased in units of the period of the loop divider (550) output signal. Each unit increase of the pulse width of the output of the PWM circuit (596) will effectively multiply the frequency output by the offset divider (590) by increasing the number of pulses swallowed by the loop divider (550). This effective multiplication will not introduce new or different spurs, nor will it effect the attenuation of fractional spurs generated by the offset divider (590). In fact, the frequency of the signal output by the PWM circuit (596) is the same as the frequency of the signal output by the frequency divider (561). The PWM circuit (596) affects only the duty cycle of the signal output by the frequency divider (561). Thus, given an octave of divide range of the frequency divider (561), coupled with the integer multiplying effect of the countdown modulus control circuit (567), the frequency synthesizer depicted in FIG. 5 exhibits a wide frequency tuning range.

When multiple accumulators (562, 563, 546 or 565) are used in the offset divider (590), fractional combination logic (566) is used to combine the carry outputs of said accumulators, as known to the art, and the resulting combination is used to periodically modify the divide value of the frequency divider (561). Some well-known combination techniques include using successive rows in a Pascal's triangle, and applying successively high-order differentiation to the carry outputs of corresponding high order accumulators and summing the results. Including the fractional spur energy from the offset divider (590), the synthesizer output signal for frequency synthesizer (500) is described by

f₀=fᵣ*(N+M/(A+Nu/D))+fₛ/(A+Nu/D)

and

f₀=fᵣ*(N−M/(A+Nu/D))+fₛ/(A+Nu/D)

for the sum and difference frequencies respectively of the loop divider (550), used as a frequency summation device, where N represents the divide modulus value of the loop divider (550), A represents the integer modulus value of the offset divider (590), Nu represents the numerator value of the offset divider (590), D represents the denominator value of the offset divider (590), M represents the pulse width increase at the output of the PWM circuit (596), as compared to the pulse width of the offset signal (525), in unit multiples of the period of the loop divider (550) output signal, fᵣ represents the reference frequency (510) and fₛ represents fractional spurs generated by the offset divider (590).

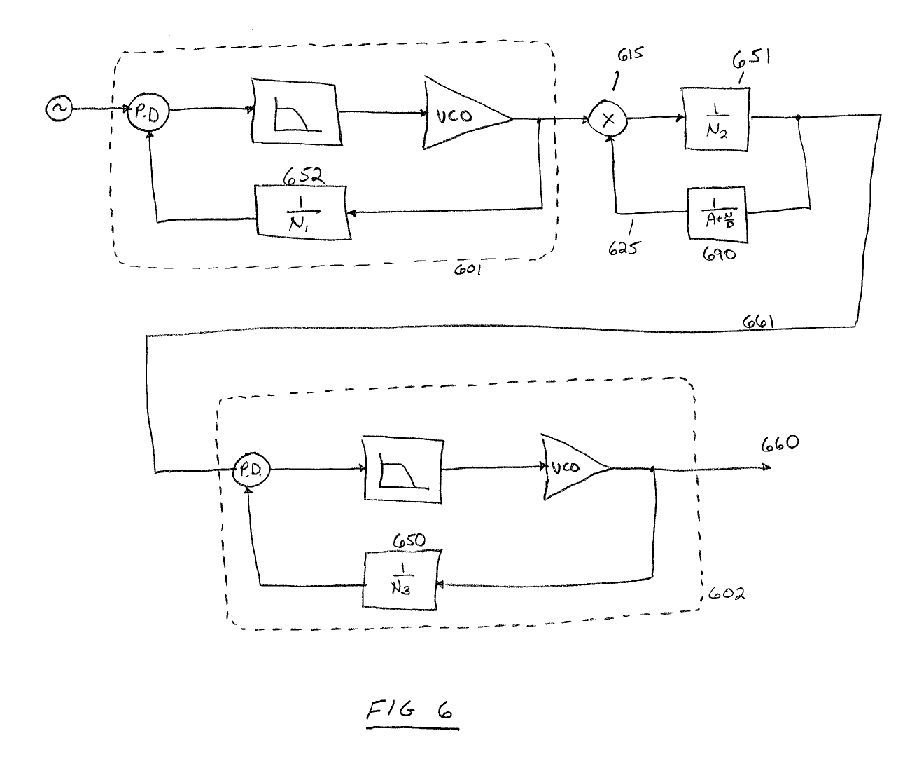

The present invention may also be configured such that the frequency summation device is not included in a feedback path. FIG. 6 illustrates an embodiment, using two conventional synthesizer loops (601 and 602). In FIG. 6 a first conventional synthesizer loop (601) provides a synthesizer reference signal (661) through a frequency summation device (625) and a reference divider (651). The output of the first synthesizer loop (601) is coupled to a first input of the frequency summation device (615). The output of the frequency summation device (615) is coupled to the input of a reference divider (651). The output of the reference divider (651) is the synthesizer reference signal (661). The synthesizer reference signal (661) is coupled to a second input of the frequency summation device (515) through an offset divider (690). The offset divider (690) is a fractional frequency divider, preferably having multiple accumulators and being capable of relatively fine frequency resolution with relatively low amplitude fractional spurs. Because the offset frequency (625) is directly related to the frequency output by the reference divider (651), aliased products will not result when the output of the frequency summation device is downsampled by the reference divider (651). Thus, the frequency summation device (615) may be an analog or digital device or may be implemented as an XOR gate or pulse swallowing frequency divider, depending on the specific configuration of the frequency synthesizer (600). Further, as has been described previously, the operation of the frequency summation device (615) and the reference divider (651) can be combined into a single dual modulus frequency divider. For such an embodiment, the offset frequency (625) would be coupled to the modulus control of the frequency divider, where the modulus control is responsive to either the positive or negative transitions of the offset signal (625). The offset divider circuit (690), while not included in a synthesizer loop, provides for potentially low valued loop divider (650 and 652) divide values, and for fractional spurs, which are reduced in amplitude by a factor of the offset divider (690) modulus value. Taking into account the fractional spurs generated by the offset divider (690) which are within the bandwidth of the frequency synthesizer (600), the synthesizer output signal (660) is described by

f₀=(fᵣ*N1/(N₂−1/(A+Nᵤ/D)))*N₃

and

f₀=(fᵣ*N1/(N₂+1/(A+Nᵤ/D)))*N₃

for the sum and difference frequencies respectively of the frequency summation device (615) where f₀ represents the output frequency of the frequency synthesizer (660), fᵣ represents the reference frequency (310), N₁ and N₄ represent the modulus values of the loop dividers (350 and 351 respectively), N₂, N₃ and N₅ represent the modulus values of dividers (353, 352, and 354) respectively, A represents the modulus value of the offset divider (690) and fₛ represents fractional spurs generated by the offset divider (690).

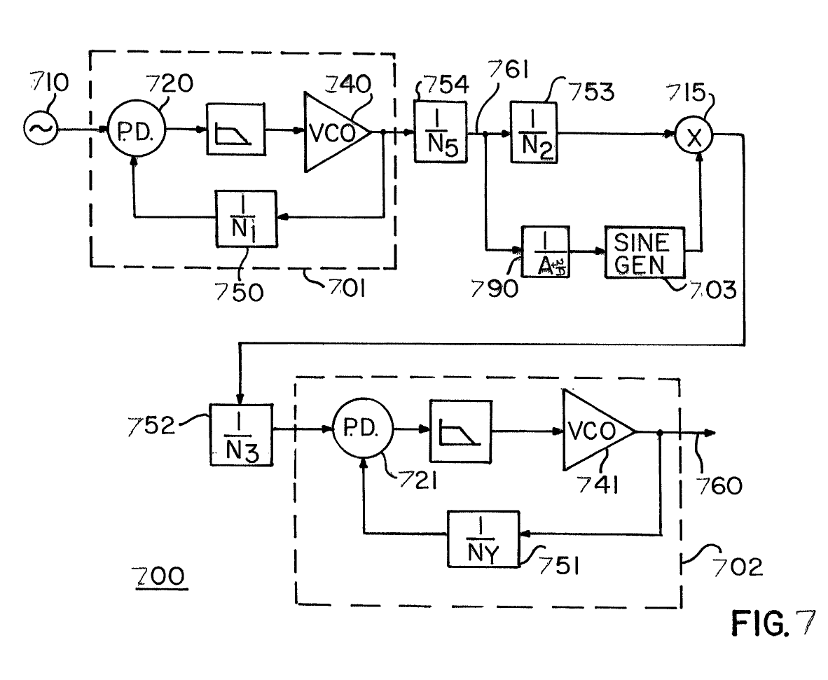

In FIG. 7 a first conventional synthesizer loop (701) provides a synthesizer reference signal (761) through a coupling divider (754). The synthesizer reference signal (761) is coupled to a first input of a frequency summation device (715) through divider N₂ (753), and is coupled to a second input of the frequency summation device (715) through an offset divider (790). The reference input of a second conventional synthesizer loop (702) is coupled to the output of the frequency summation device (715) through divider N₃ (752). The coupling divider (754) has a divide modulus of N₅, and may be used to provide a quadrature synthesizer reference signal (761). The first and second loop dividers (750 and 751 respectively) may be integer or fractional-N type frequency dividers. Dividers (753 and 752) may optionally be used in order to lower the frequency of the signal input to the second conventional synthesizer loop (702). Preferably, the offset divider (790) is a fractional frequency divider having multiple accumulators, and is capable of very fine frequency resolution with relatively low amplitude fractional subharmonic spurs.

The frequency summation device (715) is preferably embodied as an image-balanced mixer, in order to reduce aliased spurs, when dividers (753 or 752) are used having a divide value greater than 1. The output of the offset divider (790) is coupled to the second input of the frequency summation device (715) through a sine generator (702). The offset divider circuit (790), while not included in the synthesizer loop, still provides for a potentially low valued loop divider (750 and 751) divide value, and for fractional spurs, which are reduced in amplitude by a factor of the offset divider (790) modulus value. Taking into account the fractional spurs generated by the offset divider (790) which are within the bandwidth of the frequency synthesizer (700), the synthesizer output signal (760) is described by

f₀=(fᵣ*N₁*N₄/(N₃*N₅))*(1/N₂+1/A)+fₛ*N₄/(A*N₃)

and

f₀=(fᵣ*N₁*N₄/(N₃*N₅))*(1/N₂−1/A)+fₛ*N₄/(A*N₃)

for the sum and difference frequencies respectively of the image balanced mixer (715) where f₀ represents the output frequency of the frequency synthesizer (760), fᵣ represents the reference frequency (710), N₁ and N₄ represent the modulus values of the loop dividers (750 and 751 respectively), N₂, N₃ and N₅ represent the modulus values of dividers (753, 752, and 754) respectively, A represents the modulus value of the offset divider (790) and fₛ represents fractional spurs generated by the offset divider (790).

Preferably, in FIG. 7, the divide values of dividers (751 and 752) are of equal value. For this case the fractional spurs generated by the offset divider (790) are attenuated by a factor equal to A. For the frequency synthesizer (700), it may be desirable to operate the phase detector in the second conventional synthesizer loop (702) at a relatively low frequency. For this reason, it is useful to provide dividers (N₃ and N₄) with a divide value of greater than one.

While dividers (754) and (753) may optionally be used to lower the frequency of the signal input to the second conventional synthesizer loop (702), in the preferred embodiment, the dividers (754) and (753) are set to a divide value of one.

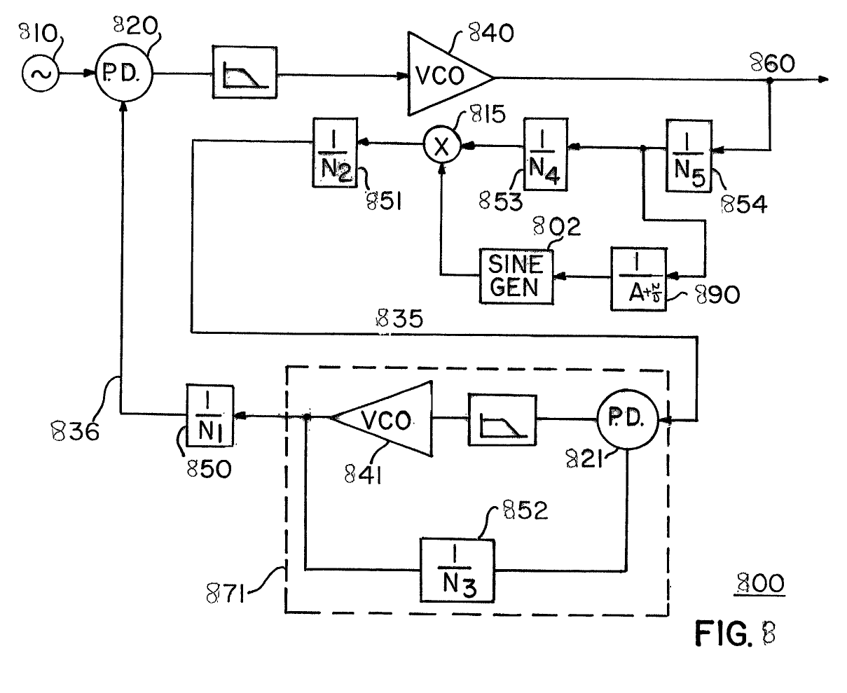

The frequency synthesizer shown in FIG. 8 comprises a modified synthesizer loop (800) which includes a feedback path (899). The feedback path (899) includes a frequency summation device (815) which has a first input coupled to the output of a secondary loop divider (853). The secondary loop divider (853) and an offset frequency divider (890) are coupled to the synthesizer output signal (960) through a coupling divider (854). The second input of the frequency summation device (815) is coupled to the output of the offset divider (890). Preferably the offset divider (890) is a fractional frequency divider having multiple accumulators, and is capable of very fine frequency resolution with relatively low amplitude fractional subharmonic spurs. The output of the frequency summation device (815) is coupled to a reference input of a conventional synthesizer loop (871) through divider (851). A second VCO (841) is coupled to the feedback input of a second phase detector (821) through divider (852). The phase-locked loop (871) has a low-pass response to frequencies output by the second phase detector (821), and as a consequence, effectively has a bandpass response to the intermediate frequency (835). Because of the bandpass response of the phase-locked loop, the signal output by the second VCO (841) will have a spectrum that substantially comprises only the fundamental input frequency of the intermediate signal (835) and harmonics of the intermediate signal (835). The first loop divider (850) is coupled to receive the signal output by the second VCO (841), and provides a feedback signal (836) to a second input of the first phase detector (820). Because the phase-locked loop (871) substantially removes all non-harmonically related frequencies from the intermediate signal (835), substantially no spurious signals, which result from aliasing, will be present at the output of the loop divider (850). The loop divider (850) is an integer or fractional frequency divider preferably used for coarse frequency tuning of the frequency synthesizer (800).

Preferably, in FIG. 8, the divide values of dividers (851 and 852) are of equal value. For this case the fractional spurs generated by the offset divider (890) are attenuated by a factor approximately equal to A. For the frequency synthesizer (800), it may be desirable to operate the phase detector in the second conventional synthesizer loop (871) at a relatively low frequency. For this reason, it is useful to provide dividers N₂ and N₃ (851 and 852 respectively) with a divide value of greater than one. Preferably, the frequency summation device (851) is an image-balanced mixer, and a sine generator (802) is used if dividers (851 and 852) have a divide value which is greater than 1.

If dividers (851 and 852) have a divide value equal to 1, or are not included, then the frequency summation device may be a digital device such as an XOR gate, or a divide by 1 or 1.5 frequency divider. For this case, it is not necessary to couple the signal output by the offset divider (890) to the second input of the frequency summation device (815) with a sine generator (802), since the intermediate frequency (835) is not downsampled and aliasing will not occur.

Because the phase-locked loop (871) has an effective bandpass response to the intermediate frequency (835), it is not necessary to provide an intermediate frequency (835) which has attenuated non-harmonically related spurs, as long as such spurs are sufficiently offset in frequency from the carrier. Consequently, if divider (851) is equal to one, the frequency summation device (815) can be either an analog device, such as an image-balanced mixer, or a digital device such as an XOR gate or a divide by 1 or 1.5 frequency divider, without producing aliased spurs at the output of the loop divider (850). In steady state, the synthesizer output signal (860) is described as a function of the reference frequency (810) by

f₀=(fᵣ*N₁*N₂*N₄*N₅*A)/N₃(N₄+A)+fₛ*N₅*N₄/(N₄+A)

and

f₀=(fᵣ*N₁*N₂*N₄*N₅*A)/N₃(N₄−A)+fₛ*N₅*N₄/(N₄−A)

where the frequency summation device (815) is configured to produce the sum and difference respectively of the synthesizer signal (860) frequency and the frequency output by the offset divider (890), and where f₀ represents the frequency of the synthesizer output signal (860), fᵣ represents the reference frequency (810), N₁ represents the divide value of the loop divider (850), N₁ represents the divide value of the synthesizer loop divider (850), N₂ and N₂ represent the divide value of dividers (851 and 852 respectively), N₄ represents the divide value of the secondary loop divider (850), N₅ represents the divide value of the coupling divider (854), A represents the divide value of the offset divider (890), and fₛ represents fractional spurs generated by the offset divider (890).

Preferably, an offset divider as used in the present invention is capable of very fine frequency resolution. Very fine frequency selection is an important characteristic of the offset divider since irrational numbers are often required to program the respective frequency synthesizers in the present invention, accurately for a particular frequency channel. If, for example, the offset divider in FIGS. 1, 2, 3, 4, 5, 6 or 7 has a frequency resolution of 1 Hz, then the output frequency of the respective frequency synthesizer will have a frequency error of no more than 1 Hz. The very fine frequency resolution of the offset dividers also enables the respective frequency synthesizer to compensate for frequency drift of the reference frequency due to temperature, through appropriate adjustments of the offset dividers to provide a substantially constant synthesizer output frequency. Further, the offset dividers may be used to digitally modulate the output of the respective frequency synthesizers directly, through the very fine tuning capability of the offset dividers. By correctly programming the offset dividers over time, it is possible for any of the previously described embodiments of the present invention to directly produce band limited modulated signals such as minimum shift keying (MSK) and gaussian minimum shift keying (GMSK). The offset dividers may also be used to provide automatic frequency correction (AFC) in communications transmitters and receivers.

In general, less fractionalization is necessary for the present invention than for conventional single loop frequency synthesizers for the same frequency resolution or step size. Less fractionalization is required because in a conventional single loop frequency synthesizer, the minimum output frequency resolution is measured at the input of the loop divider. In the present invention, the minimum output frequency resolution is measured at the output of the offset dividers, also referred to as an offset signal. Therefore, if the offset signal is not multiplied at the output of a frequency synthesizer, an offset divider, as used in the present invention, will have N times the frequency resolution of a fractional N loop divider used in a conventional single loop architecture, where N equals the divide value of the offset and fractional N loop dividers.

Multiple frequency synthesizer topologies have been described which enable fractional N frequency dividers to be used in phase-locked loop type frequency synthesizers, with a significantly lower fractional noise contribution as compared to fractional N frequency synthesizers known to the prior art. In general, this has been accomplished by adding, in the frequency domain, the output signal of a fractional N frequency divider to a relatively high frequency signal within the frequency synthesizer. Using this technique, the output signal of the fractional N frequency divider is not multiplied by the loop gain of the frequency synthesizer, and therefore the fractional noise is kept to relatively low levels. Numerous modifications, changes, variations, substitutions and equivalents will occur to those skilled in the art without departing fromt the spirit and scope of the present invention as defined by the appended claims.

What is claimed is:

1. A frequency synthesizer comprising:
a modified synthesizer loop having a feedback path and a synthesizer output signal, the feedback path comprising a frequency summation device having a first input coupled to the synthesizer output signal, and a second input coupled to the synthesizer output signal through an offset divider.

2. A frequency synthesizer as in claim 1 wherein the offset divider is a fractional frequency divider having at least two accumulators.

3. A frequency synthesizer as in claim 2 further comprising a conventional synthesizer loop coupled to receive an intermediate signal output from the frequency summation device, and a loop divider operatively coupled to an output of the phase-locked loop, the loop divider providing a feedback signal.

4. A frequency synthesizer comprising:
an intermediate frequency;
a modified synthesizer loop having a feedback path and a synthesizer output signal, the feedback path including a frequency summation device and an offset divider, the offset divider providing an offset frequency signal;
the frequency summation device having first and second inputs, the first input coupled to the synthesizer output signal, the intermediate frequency coupled to the second input through the offset divider; and
wherein the offset divider is a fractional frequency divider having a periodically modified divide modulus.

5. A frequency synthesizer as in claim 4 wherein the divide modulus is periodically modified by at least two accumulators.

6. A frequency synthesizer as in claim 5 further comprising a loop divider coupled to receive the output of the frequency summation device, the output of the frequency divider providing the intermediate frequency.

7. A frequency synthesizer as in claim 6 wherein the frequency summation device is a digital frequency summation device.

8. A frequency synthesizer as in claim 5 wherein said frequency summation device is a pulse swallowing loop divider having a modulus control, the modulus control coupled to the offset frequency signal, the offset frequency signal having periodic cycles, the modulus control responsive to each periodic cycle.

9. A frequency synthesizer as in claim 8 wherein the offset frequency signal is coupled to the modulus control through a pulse width modulator, each cycle of the offset frequency signal having a pulse width, the pulse width modulator having an output and selectively modifying said pulse width of the offset frequency signal in unit increments of the intermediate frequency at said output.

9. A frequency synthesizer comprising:
an intermediate frequency;
a reference frequency,
a modified synthesizer loop having a feedback path and a synthesizer output signal, the feedback path including a frequency summation device and an offset divider, the offset divider providing an offset frequency;
the frequency summation device having first and second inputs, the first input coupled to the synthesizer output signal, the reference frequency coupled to the second input through the offset divider; and
wherein the offset divider is a fractional frequency divider having at least two accumulators.

10. A frequency synthesizer comprising:
a conventional synthesizer loop having a reference input;
a reference frequency
a frequency summation device having a first input coupled to receive the reference frequency, an output coupled to the reference input and a second input coupled to said output through an offset divider; and
the offset divider is a fractional frequency divider having at least two accumulators.

11. A frequency synthesizer as in claim 10 wherein the offset divider outputs an offset frequency signal having periodic cycles and wherein the frequency summation device is a pulse swallowing loop divider having a modulus control input coupled to receive the offset frequency signal, the modulus control input responsive to cycles of the offset frequency signal.

12. A frequency synthesizer as in claim 11 further comprising a conventional synthesizer loop, the conventional synthesizer loop providing the reference signal.

13. A frequency synthesizer comprising:
a first conventional synthesizer loop having a reference input;
a frequency summation device having an output coupled to the reference input, and;
a reference frequency coupled to a first input of the frequency summation device and coupled to a second input through an offset divider.

14. A frequency synthesizer as in claim 13 further comprising a second conventional synthesizer loop providing the reference frequency.
